(19) United States
(12) Patent Application Publication
(10) Pub. No.: US 2013/0341610 A1
(43) Pub. Date: Dec. 26, 2013

(54) TRANSPARENT ORGANIC LIGHT EMITTING DIODE LIGHTING DEVICE

(71) Applicant: Electronics and Telecommunications Research Institute, Daejeon (KR)

(72) Inventors: Hye Yong CHU, Daejeon (KR); Jeong Ik Lee, Gyeonggi-do (KR); Jong Hee Lee, Daejeon (KR); Kyoung Ik Cho, Daejeon (KR)

(21) Appl. No.: 13/974,995

(22) Filed: Aug. 23, 2013

Related U.S. Application Data
(62) Division of application No. 12/727,632, filed on Mar. 19, 2010.

(30) Foreign Application Priority Data
Mar. 20, 2009 (KR) 10-2009-0023932
Mar. 16, 2010 (KR) 10-2010-0023167

(51) Int. Cl. H01L 27/32

(52) U.S. Cl. CPC H01L 27/3227
USPC 257/40; 257/84

(57) ABSTRACT

Provided is a transparent organic light emitting diode (OLED) lighting device in which opaque metal reflectors are formed to adjust light emitting directions. The transparent OLED lighting device includes a transparent substrate, a transparent anode formed on a predetermined region of the transparent substrate, a reflective anode formed adjacent to the transparent anode on another region of the transparent substrate, an organic layer formed on the transparent and reflective anodes, and a transparent cathode and an encapsulation substrate sequentially stacked on the organic layer. Directions of light emitted from the organic layer vary depending on the current applied to the transparent and reflective anodes.

### CROSS-REFERENCE TO RELATED APPLICATION

This is a divisional of co-pending U.S. application Ser. No. 12/727,632, filed Mar. 19, 2010. This application claims priority to and the benefit of Korean Patent Application Nos. 10-2009-0023932 filed Mar. 20, 2009, and 10-2010-0023167 filed Mar. 16, 2010, the disclosure of which is incorporated herein by reference in its entirety.

### BACKGROUND

1. Field of the Invention

The present invention relates to a transparent organic light emitting diode (OLED) lighting device and, more particularly, to a transparent OLED lighting device in which opaque metal reflectors are formed to control light emitting directions.

2. Discussion of Related Art

Recently, the display industry has been developed in response to demands for small size, light weight, and thin thickness using thin films, as well as high resolution. According to this demand, research on display devices that embody the small size, light weight, and thin thickness using a plastic or metal thin film as a substrate instead of liquid crystal display (LCD) devices using a glass substrate or display devices using organic electroluminescence characteristics is under way. To embody a next-generation plastic display, known device manufacturing techniques, organic electroluminescence device techniques are attracting attention as the most practical technology.

Further, lighting devices using an organic light emitting diode (OLED) may be divided into a top emission type, a bottom emission type, and a double-sided emission type (i.e., a transparent type) depending on a light emitting direction.

Here, the top or bottom emission type OLED lighting devices are not transparent, and thus cannot be used as window type lighting devices. Thus, the double-sided emission type OLED lighting devices (or the transparent OLED lighting devices) in which both positive and negative electrodes are transparent are used as the window type lighting devices.

However, in the case of the transparent OLED lighting devices in which bidirectional lighting is possible, a user cannot control a light emitting direction when intending to send light only in one direction according to a purpose. Further, when intending to recognize an object opposite the lighting device, the user cannot recognize the opposite object under the bidirectional lighting from light of the lighting device.

For this reason, a variety of light emitting systems, each of which has at least two light emitting devices, for instance OLEDs, have recently been developed into double-sided light emitting systems in which light output is possible on opposite sides.

However, these double-sided light emitting devices can control only color and quantity of the emitted light, but not a direction of the emitted light.

### SUMMARY OF THE INVENTION

The present invention is directed to a transparent organic light emitting diode (OLED) lighting device for controlling directions in which light is emitted.

An aspect of the present invention provides a transparent organic light emitting diode (OLED) lighting device including: a transparent substrate; a transparent anode formed on a predetermined region of the transparent substrate; a reflective anode formed adjacent to the transparent anode on another region of the transparent substrate; an organic layer formed on the transparent and reflective anodes; and a transparent cathode and an encapsulation substrate sequentially stacked on the organic layer. Direction of light emitted from the organic layer emits light are controlled according to the current applied to the transparent and reflective anodes.

Another aspect of the present invention provides a transparent OLED lighting device including: a transparent substrate; a transparent anode formed on the transparent substrate; an organic layer formed on the transparent anode; a transparent cathode and an encapsulation substrate sequentially formed on the organic layer; and a metal reflector formed on one region of a lower or upper surface of the encapsulation substrate. Light emitted from the organic layer is reflected from the metal reflector.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a cross-sectional view of a transparent OLED lighting device according to a first exemplary embodiment of the present invention;

FIG. 2 illustrates arrangement of electrodes of the transparent OLED lighting device according to a first exemplary embodiment of the present invention;

FIG. 3A illustrates the state in which solar cells and a storage battery are applied to the transparent OLED lighting device according to a first exemplary embodiment of the present invention;

FIG. 3B illustrates the state in which a sensor is attached to the transparent OLED lighting device according to a first exemplary embodiment of the present invention;

FIG. 4A to FIG. 4C illustrate light emitting directions of the transparent OLED lighting device according to a first exemplary embodiment of the present invention;

FIG. 5A and FIG. 5B are cross-sectional views of a transparent OLED lighting device according to a second exemplary embodiment of the present invention;

FIG. 6A illustrates the state in which solar cells are applied to the transparent OLED lighting device according to a second exemplary embodiment of the present invention; and

FIG. 6B illustrates the state in which a sensor is attached to the transparent OLED lighting device according to a second exemplary embodiment of the present invention.

### DETAILED DESCRIPTION OF EXEMPLARY EMBODIMENTS

The present invention will be described more fully hereinafter with reference to the accompanying drawings, in which exemplary embodiments of the invention are shown. This invention may, however, be embodied in different forms and should not be construed as limited to the embodiments set forth herein. In the following description of the present invention, a detailed description of known functions and components incorporated herein will be omitted when it may make the subject matter of the present invention rather unclear. It should be noted that the same reference numbers are used in the figures to denote the same elements.

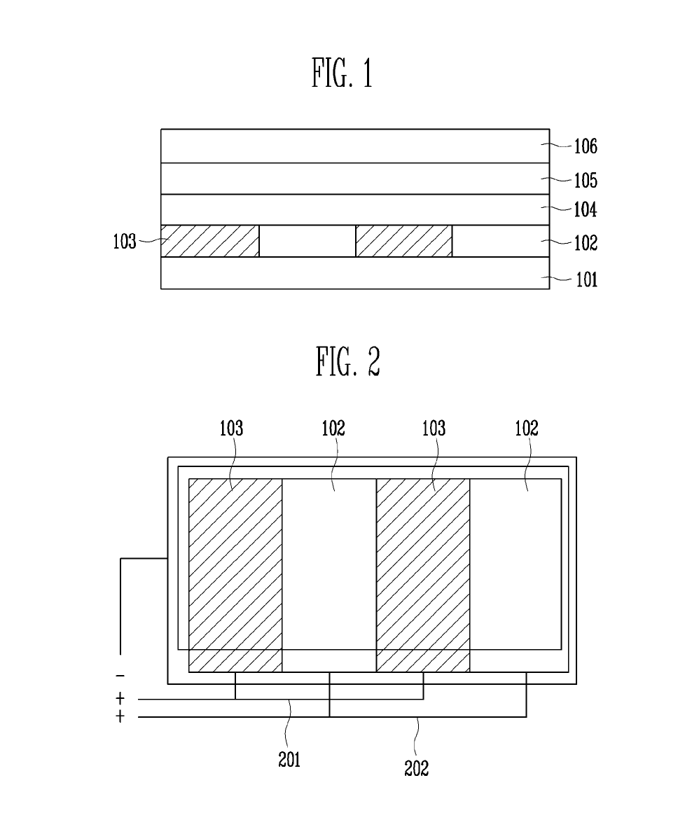

FIG. 1 is a cross-sectional view of a transparent OLED lighting device according to a first exemplary embodiment of the present invention.

Referring to FIG. 1, a transparent OLED lighting device according to the first exemplary embodiment of the present invention includes a transparent substrate 101, a transparent anode 102 formed on a predetermined region of the transparent substrate 101, a reflective anode 103 formed adjacent to the transparent anode 102 on another predetermined region of the transparent substrate 101, an organic layer 104 formed as an emissive layer on the transparent and reflective anodes 102 and 103, and a transparent cathode 105 and an encapsulation substrate 106 sequentially stacked on the organic layer 104.

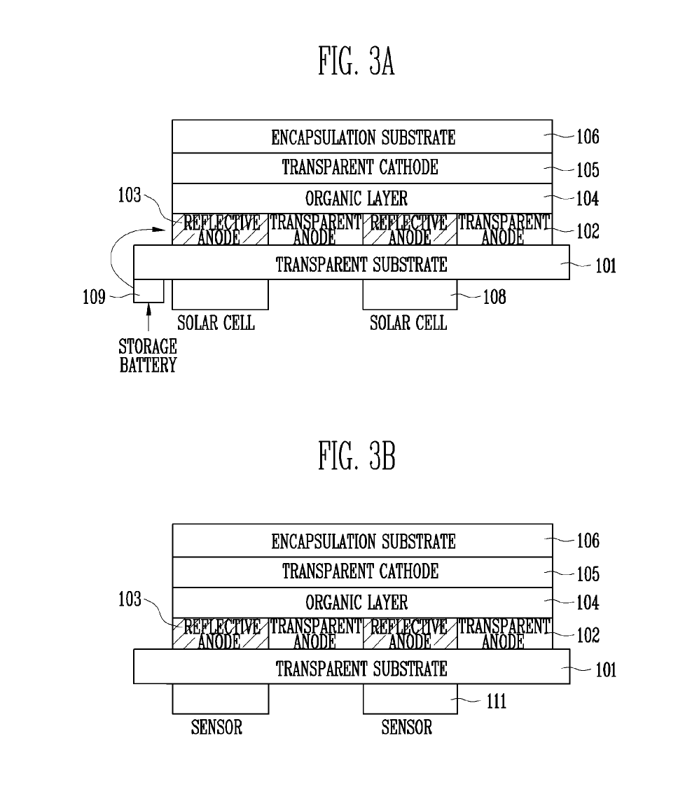

A process of manufacturing the transparent OLED lighting device according to the first exemplary embodiment of the present invention will be described with reference to FIGS. 1 and 2.

FIG. 2 illustrates arrangement of electrodes of the transparent OLED lighting device according to the first exemplary embodiment of the present invention.

In the transparent OLED lighting device according to the first exemplary embodiment of the present invention, a transparent anode 102 is formed on a transparent substrate 101. A part of the transparent anode 102 is etched, and a reflective anode 103 is deposited on the part of the transparent anode 102. Here, the transparent substrate 101 may be formed of glass or plastic. The transparent anode 102 may be formed of a transparent conductive material having a high work function, for instance indium tin oxide (ITO) or indium zinc oxide (IZO). Further, the reflective anode 103 may be formed of an opaque material such as silver (Ag) or aluminum (Al).

After the transparent and reflective anodes 102 and 103 are formed on the transparent substrate 101 in alternating arrangement by the etching process of the transparent anode 102 and the deposition process of the reflective anode 103, an organic layer 104, which is an organic emissive layer having a three-wavelength white light emitting characteristic, is formed on the transparent and reflective anodes 102 and 103 having the alternating arrangement. Meanwhile, in the exemplary embodiment of the present invention, the transparent and reflective anodes 102 and 103 are alternately arranged at a ratio of 50:50. However, the ratio of the transparent anodes 102 to the reflective anodes 103 may be changed into a specific ratio of 20:80 or 30:70. As long as the reflective anode 103 intervenes between the transparent anodes 102, any ratio will do. Further, in the exemplary embodiment of the present invention, only the organic layer 104 is implemented as the emissive layer. However, to further activate the injection of electric charges, a hole injection layer (not shown), a hole transport layer (not shown), an emissive layer (not shown), an electron transport layer (not shown), and/or an electron injection layer (not shown) may be sequentially formed.

After the organic layer 104 is formed on the transparent and reflective anodes 102 and 103, a transparent cathode 105 and an encapsulation substrate 106 are sequentially stacked on the organic layer 104. Thereby, the OLED lighting device is completed. Here, the encapsulation substrate 106 may be formed of glass or plastic. The transparent cathode 104 may be formed of a transparent conductive material having a high work function, for instance ITO or IZO. Further, in the exemplary embodiment of the present invention, the transparent anode 102 is formed on the entire surface of the transparent substrate 101 and partially etched, and then the reflective anode 103 is deposited on the etched transparent anode 102. However, if the transparent and reflective anodes 102 and 103 are formed in the alternating arrangement, the reflective anode 103 may be formed on the entire surface of the transparent substrate 101 and partially etched, and then the transparent anode 102 may be deposited on the etched reflective anode 103.

Meanwhile, when the OLED lighting device is formed by the aforementioned process, the transparent and reflective anodes 102 and 103 formed on the transparent substrate 101 are configured to be independently supplied with currents through different paths 201 and 202, as illustrated in FIG. 2. As such, by controlling flows of the current supplied to the transparent and reflective anodes 102 and 103 respectively, a direction in which the transparent OLED lighting device emits light can be controlled in such a manner that the light is emitted in opposite directions or partially emitted.

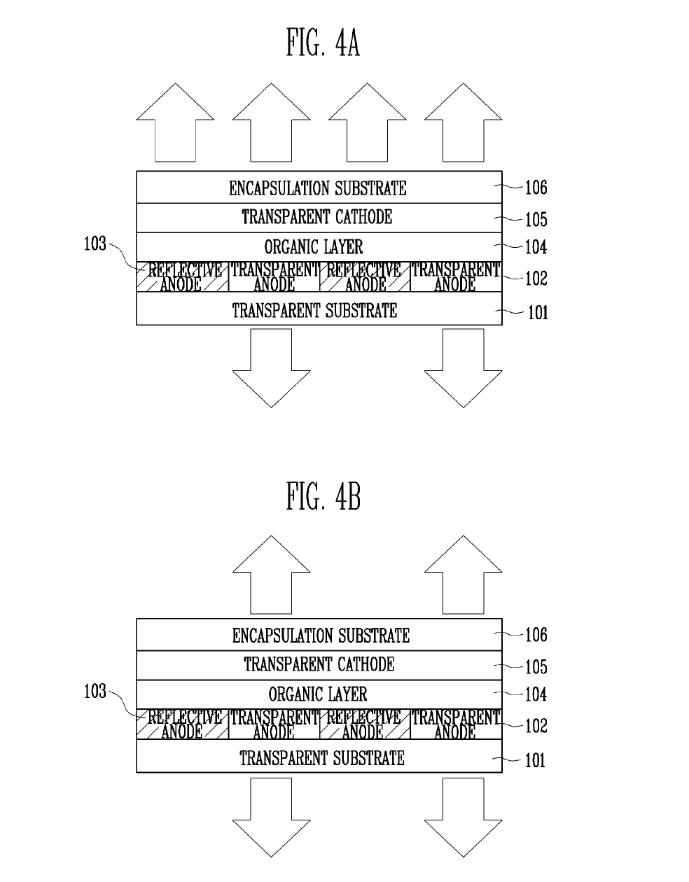

FIG. 3A illustrates the state in which solar cells and a storage battery are applied to the transparent OLED lighting device according to the first exemplary embodiment of the present invention.

Referring to FIG. 3A, a transparent OLED lighting device to which solar cells and a storage battery are applied in accordance with the first exemplary embodiment of the present invention includes transparent and reflective anodes 102 and 103 formed on a transparent substrate 101 in alternating arrangement, an organic layer 104 formed on the transparent and reflective anodes 102 and 103 having the alternating arrangement, and a transparent cathode 105 and an encapsulation substrate 106 sequentially formed on the organic layer 104.

Further, the solar cells 108 are formed on some regions of a lower surface of the transparent substrate 101 to be symmetrical with respect to the reflective anode 103 formed on the transparent substrate 101. The storage battery 109 is formed on one region of the lower surface of the transparent substrate 101 which has no solar cell 108.

Here, each solar cell 108 may include a silicon semiconductor based solar cell, a copper indium gallium selenide (CIGS) based solar cell, or an organic compound based solar cell. The storage battery 109 formed on one region of the transparent OLED lighting device can store electricity generated through the solar cells 108. In the exemplary embodiment of the present invention, the storage battery 109 is formed under the transparent substrate 101. However, the storage battery 109 may be formed on any region of the transparent OLED lighting device as long as it can store the electricity generated through the solar cells 108.

FIG. 3B illustrates the state in which a sensor is attached to the transparent OLED lighting device according to a first exemplary embodiment of the present invention

Referring to FIG. 3B, the transparent OLED lighting device to which the sensor is attached according to the first exemplary embodiment includes a transparent anode 102 and a reflective anode 103 that are alternately arranged on a transparent substrate 101, an organic layer 104 formed on the transparent anode 102 and the reflective anode 103 that are alternately arranged, and a transparent cathode 105 and an encapsulation substrate 106, which are sequentially stacked on the organic layer 104. Also, the lighting device includes a sensor 111 formed below of the transparent substrate 101 to be symmetrical with the reflective anode 103 formed on the transparent substrate 101.

As described above, when the sensor 111 is attached to the transparent OLED lighting device, it enables a user to recognize an object opposite the transparent OLED lighting device under lighting. Also, the sensor 111 is installed on rear surfaces of the metal reflectors which are made up of opaque regions, so that it can sense a change in surroundings to be utilized for changing lighting.

Here, a silicon semiconductor-based sensor, or an organic compound-based sensor may be used as the sensor 111.

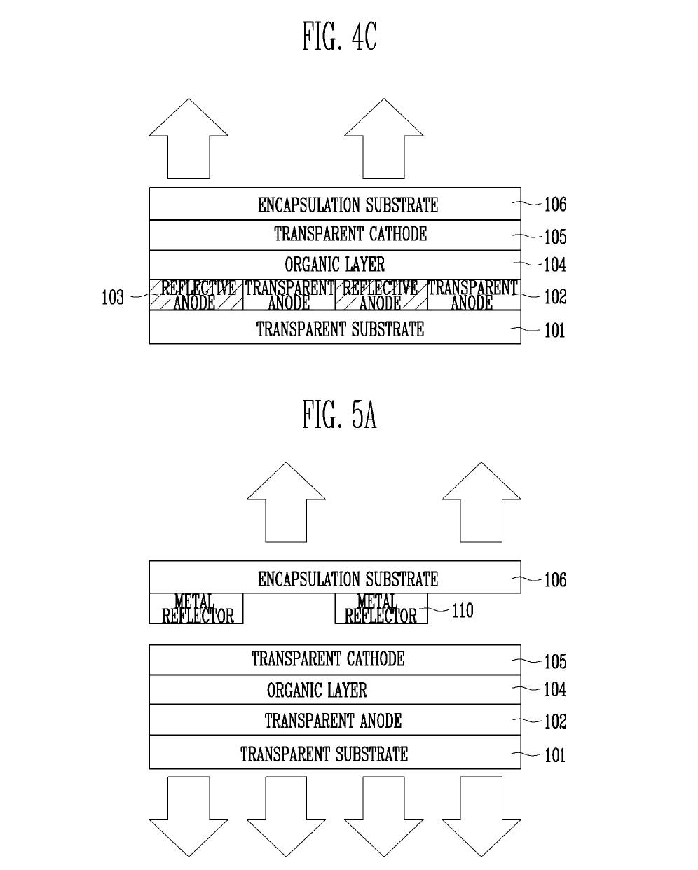

FIG. 4A to FIG. 4C illustrate light emitting directions of the transparent OLED lighting device according to the first exemplary embodiment of the present invention.

The transparent OLED lighting device according to the first exemplary embodiment of the present invention controls a current applied to the transparent anode 102, the reflective anode 103, and the transparent cathode 105. Thereby, as indicated by arrows in FIG. 4, light emitting directions of the transparent OLED lighting device are controlled.

FIG. 4A illustrates directions in which light is emitted from a transparent OLED lighting device when a current is applied to a transparent anode 102, a reflective anode 103, and a transparent cathode 105. First, when the current is applied to the transparent anode 102 and the reflective anode 103, and when the current is applied to the transparent cathode 105, holes migrate from the transparent and reflective anodes 102 and 103 to the organic layer 104, and electrons migrate from the transparent cathode 105 to the organic layer 104. Then, the holes and electrons migrating to the organic layer 104 are combined to emit light. The light emitted from the organic layer 104 passes through the transparent anode 102 and the transparent cathode 105, and is emitted from opposite surfaces of the transparent OLED lighting device. The light incident on the region where the reflective anode 103 is formed is reflected from the reflective anode 103 toward the transparent cathode 105. Thus, as illustrated in FIG. 4A, when the current is applied to the transparent anode 102, the reflective anode 103, and the transparent cathode 105 of the transparent OLED lighting device, the light is emitted to one region of the lower surface of the transparent substrate 101 and an entire upper surface of the encapsulation substrate 106. In particular, by the alternating arrangement of the reflective anode 103 and the transparent anode 102, the light emitting directions in which the light is emitted from the opposite surfaces of the transparent OLED lighting device can be controlled.

FIG. 4B illustrates directions in which light is emitted from a transparent OLED lighting device when a current is applied to transparent anode 102 and a transparent cathode 105.

First, when the current is applied to the transparent anode 102 and the transparent cathode 105, holes migrate from the transparent anode 102 to the organic layer 104, and electrons migrate from the transparent cathode 105 to the organic layer 104. Then, the holes and electrons migrating to the organic layer 104 are combined to emit light. The emitted light travels in opposite directions of each transparent anode 102. Here, since no current is applied to the reflective anode 103, the reflective anode 103 can function as a mirror. As such, a user can recognize an object in the state where the light is emitted.

FIG. 4C illustrates directions in which light is emitted from a transparent OLED lighting device when a current is applied to reflective anode 103 and a transparent cathode 105.

First, when the current is applied to the reflective anode 103 and the transparent cathode 105, holes and electrons migrate from the reflective anode 103 and the transparent cathode 105 to the organic layer 104, and are combined to emit light from the organic layer 104. The light emitted from the organic layer 104 in opposite directions is reflected from the reflective anode 103, so that the light is emitted only in one direction in which the upper surface of each reflective anode 103 is located. As such, the user can recognize an object located opposite the transparent OLED lighting device through the transparent anode 102 to which no current is applied.

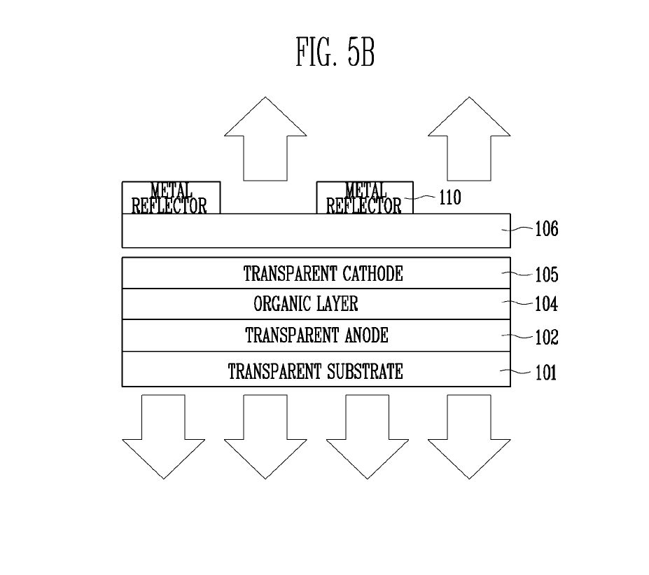

FIG. 5A and FIG. 5B are cross-sectional views of a transparent OLED lighting device according to a second exemplary embodiment of the present invention.

Referring to FIGS. 5A and 5B, a transparent OLED lighting device according to the second exemplary embodiment of the present invention includes a transparent substrate 101, a transparent anode 102, an organic layer 104, a transparent cathode 105, an encapsulation substrate 106, and metal reflectors 110.

A process of manufacturing the transparent OLED lighting device according to the second exemplary embodiment of the present invention will be described with reference to FIGS. 5A and 5B.

First, a transparent anode 102 is formed on a transparent substrate 101 to apply a current. An organic layer 104 is formed as an emissive layer on the transparent anode 102.

In this manner, after the transparent anode 102 and the organic layer 104 are sequentially stacked on the transparent substrate 101, a transparent cathode 105 and an encapsulation substrate 106 are sequentially stacked on the organic layer 104. Here, the transparent substrate 101 and the encapsulation substrate 106 may be formed of glass or plastic.

In the transparent OLED lighting device according to the second exemplary embodiment of the present invention, as illustrated in FIGS. 5A and 5B, a metal reflector 110 may be further formed on one region of an upper or lower surface of the encapsulation substrate 106. The metal reflector 110 may be formed of Ag or Al.

Thus, in the transparent OLED lighting device according to the second exemplary embodiment of the present invention, the metal reflector 110 is formed on one region of the upper or lower surface of the encapsulation substrate 106, so that as indicated by arrows in FIGS. 5A and 5B, light can be controlled to be emitted to an entire lower surface of the transparent substrate 101 and one region of the upper surface of the encapsulation substrate 106.

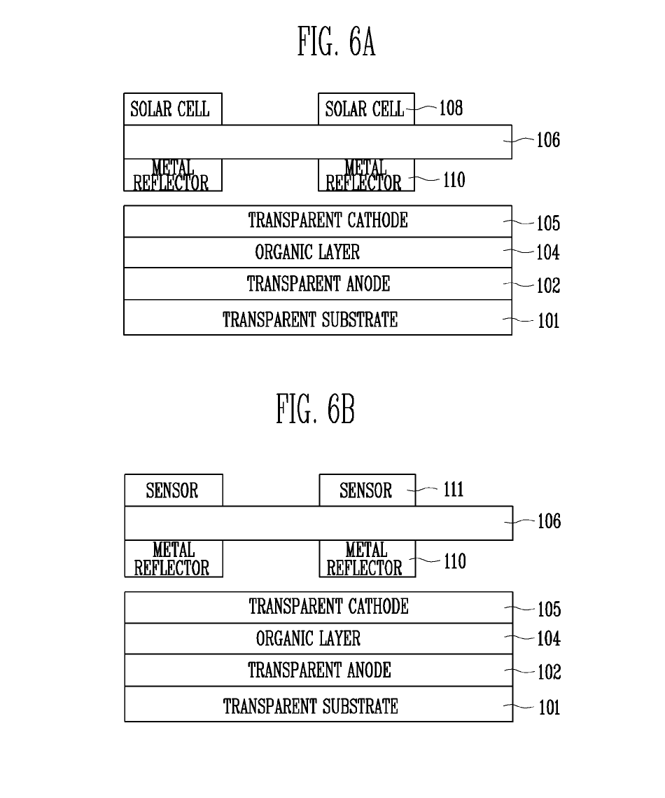

FIG. 6A illustrates the state in which solar cells are applied to the transparent OLED lighting device according to the second exemplary embodiment of the present invention.

Referring to FIG. 6A, a transparent OLED lighting device to which solar cells are applied in accordance with the second exemplary embodiment of the present invention includes a transparent substrate 101, a transparent anode 102, an organic layer 104, a transparent cathode 105, an encapsulation substrate 106, and a solar cell 108.

Here, the solar cells 108 may be formed on the encapsulation substrate 106 to be symmetrical with respect to the metal reflector 110 formed under the encapsulation substrate 106.

FIG. 6B illustrates the state in which a sensor is attached to the transparent OLED lighting device according to a second exemplary embodiment of the present invention.

Referring to FIG. 6B, the transparent OLED lighting device to which the sensor is attached according to the second exemplary embodiment includes a transparent substrate 101, a transparent anode 102, an organic layer 104, a transparent cathode 105, an encapsulation substrate 106, and a sensor 111.

Here, the sensor 111 may be formed on the encapsulation substrate 106, and may be formed on a region to be symmetrical with a metal reflectors 110 formed below the encapsulation substrate 106.

The transparent OLED lighting device formed through the aforementioned process in accordance with the second exemplary embodiment of the present invention emits light from the organic layer 104 to opposite surfaces thereof through the transparent anode 102 and the transparent cathode 105. However, due to the metal reflector 110 formed on one region of the upper or lower surface of the encapsulation substrate 106, the light emitted to the upper surface of the transparent OLED lighting device is emitted only from one region of the upper surface of the encapsulation substrate 106 rather than an entire upper surface of the encapsulation substrate 106, as indicated by arrows in FIGS. 5A and 5B.

As described above, since the opaque metal reflector 103 or 110 is deposited on one region of the transparent anode 102 or the encapsulation substrate 106, it is possible to control the light emitting directions of the transparent OLED lighting device.

According to exemplary embodiments of the present invention, a transparent OLED lighting device controls light emitting directions such that light is not emitted in an undesired direction, so that it can be used for unidirectional lighting or bidirectional lighting according to a purpose.

Further, the transparent OLED lighting device enables a user to recognize an object opposite the transparent OLED lighting device under lighting. Solar cells are installed on rear surfaces of the metal reflectors which are made up of opaque regions, so that the transparent OLED lighting device can store electricity and thus save energy.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A transparent organic light emitting diode (OLED) lighting device comprising:
a transparent substrate;
a transparent anode formed on the transparent substrate;
an organic layer formed on the transparent anode;
a transparent cathode and an encapsulation substrate sequentially formed on the organic layer; and
a metal reflector formed on one region of a lower or upper surface of the encapsulation substrate,
wherein the organic layer emits light, which is reflected from the metal reflector.

2. The transparent OLED lighting device according to claim 1, further comprising a solar cell formed on one region of the upper surface of the encapsulation substrate.

3. The transparent OLED lighting device according to claim 2, wherein the solar cell is formed to be symmetrical with respect to the metal reflector formed under the encapsulation substrate.

4. The transparent OLED lighting device according to claim 1, further comprising a sensor formed on a region of the encapsulation substrate.

5. The transparent OLED lighting device according to claim 4, wherein the sensor is formed on a region to be symmetrical with the metal reflectors formed below the encapsulation substrate.

6. The transparent OLED lighting device according to claim 1, wherein when a current is applied to the transparent anode and the transparent cathode, the light is emitted to an entire lower surface of the transparent substrate and one region of the upper surface of the encapsulation substrate which have no metal reflectors.

7. The transparent OLED lighting device according to claim 1, wherein the transparent substrate and the encapsulation substrate are formed of glass or plastic.

8. The transparent OLED lighting device according to claim 1, wherein the metal reflector is formed of silver (Ag) or aluminum (Al).
